(19) United States
(12) Patent Application Publication
(10) Pub. No.: US 2026/0301616 A1
(43) Pub. Date: Oct. 1, 2026

(54) MECHANICAL NON-BINARY DISPLAY UNIT

(71) Applicant: BREAKFAST, LLC, Brooklyn, NY (US)

(72) Inventors: Andrew Zolty, Nyack, NY (US); Andrew Laska, Brooklyn, NY (US); Andrew McIntyre, Brooklyn, NY (US); Mohammad Hosein Asgari, Brooklyn, NY (US); Michael Fazio, Cromwell, CT (US); Jason Cipriani, Brooklyn, NY (US)

(21) Appl. No.: 19/634,738

(22) Filed: Mar. 31, 2026

Related U.S. Application Data
(60) Provisional application No. 63/781,788, filed on Apr. 1, 2025.

(51) Int. Cl. G09G 3/00; H05K 5/02

(52) U.S. Cl. CPC G09G 3/001; H05K 5/0217; G09G 2360/04

(57) ABSTRACT

One variation of a system includes a display unit including: a chassis; a flap pivotably coupled to the chassis; a tappet extending from the chassis toward the flap; an actuator arranged in the chassis; and a local controller. The flap: includes a front surface and a rear surface, opposite the front surface, oriented toward the chassis; and is configured to pivot over a range of angular pitch orientations. The tappet is configured: to advance toward the flap to angularly displace the flap from the neutral pitch orientation; and to retract from the flap to permit the flap to oscillate through the range of angular pitch orientations. The local controller is configured to trigger the actuator: to advance the tappet toward the flap; and to retract the tappet to separate the tappet from the flap.

### CROSS-REFERENCE TO RELATED APPLICATIONS

This Application claims the benefit of U.S. Provisional Application No. 63/781,788, filed on 1 Apr. 2025, which is incorporated in its entirety by this reference.

This Application is related to U.S. patent application Ser. No. 17/067,117, filed on 9 Oct. 2020, which claims the benefit of U.S. Provisional Application No. 62/913,084, filed on 9 Oct. 2019, each of which is incorporated in its entirety by this reference.

### TECHNICAL FIELD

This invention relates generally to the field of mechanical displays and, more specifically, to a new and useful mechanical non-binary display unit in the field of mechanical displays.

### BRIEF DESCRIPTION OF THE FIGURES

FIGS. 1A and 1B are flowchart representations of a method;

FIGS. 2A and 2B are flowchart representations of one variation of the method;

FIG. 3 is a flowchart representation of one variation of the method;

FIG. 4 is a schematic representation of a system; and

FIGS. 5A and 5B are schematic representations of the system.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Method

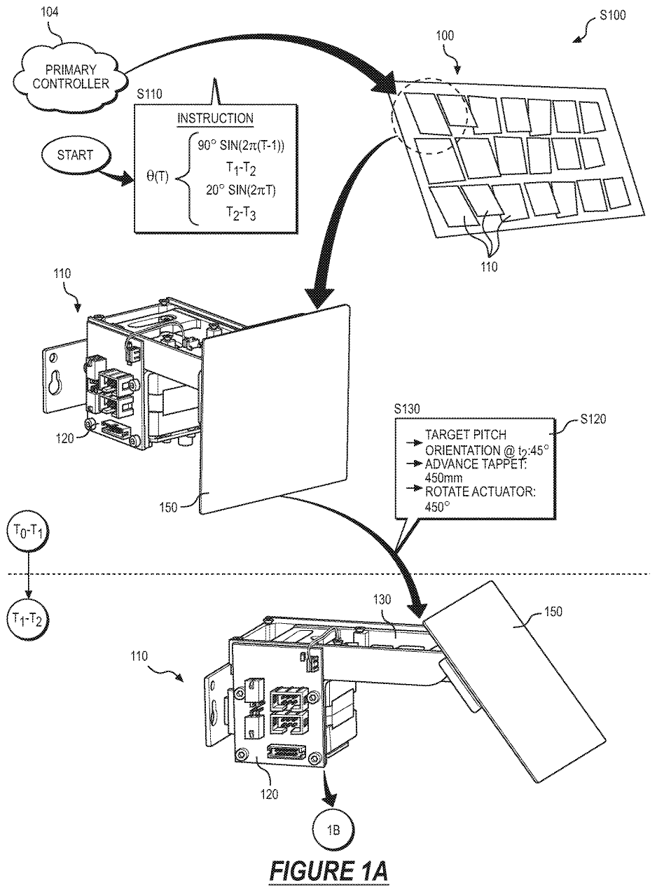

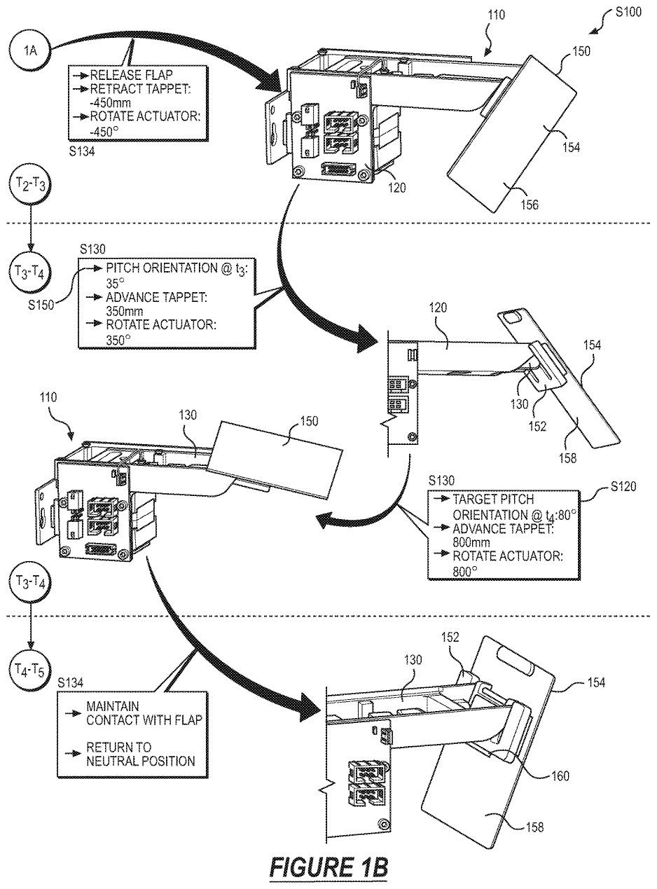

As shown in FIGS. 1A, 1B, 2A, 2B, 3, 4, 5A, and 5B, a method S100 includes, at a display unit 110: receiving an instruction assigned to the display unit 110 by a primary controller 104 in Block S110; and, based on the instruction, deriving a target pitch orientation for angularly displacing a flap 150, pivotably coupled to a chassis 120 of the display unit 110, at a first time in Block S120.

The method S100 also includes, via an actuator 140 of the display unit 110: advancing a tappet 130, interposed between the chassis 120 and the flap 150, toward the flap 150 to locate the tappet 130 in contact with the flap 150 and angularly displace the flap 150 from a neutral pitch orientation 114 toward the target pitch orientation at the first time in Block S130; and retracting the tappet 130 from the flap 150 to separate the tappet 130 from the flap 150 and permit the flap 150 to oscillate in Block S134.

### 2. System

A display system 100 includes: a primary controller 104; a first set of display units 110 arranged in a first column and electrically connected in series; a first column controller 106; a second set of display units 110 arranged in a second column adjacent the first column, electrically connected in series, and cooperating with the first set of display units 110 to form a multi-panel display 108; and a second column controller 106.

The first column controller 106: is coupled to the first set of display units 110; and is configured to serve a first set of actuation instructions, received from the primary controller 104, to local controllers 112 in the first set of display units 110. The first set of display units 110 are configured to execute the first set of actuation instructions to manipulate (e.g., pitch) flaps 150 of the first set of display units 110.

The second column controller 106: is coupled to the second set of display units 110; and configured to serve a second set of actuation instructions, received from the primary controller 104, to local controllers 112 in the second set of display units 110. The second set of display units 110 is configured to execute the second set of actuation instructions: to manipulate flaps 150 of the second set of display units 110; and to cooperate with the first set of display units 110 to generate a dynamic visual effect across the multi-panel display 108.

### 2.1 Display Unit

As shown in FIGS. 1A, 1B, 2A, 2B, 3, 4, 5A, and 5B, a display unit 110 includes: a chassis 120; a flap 150 pivotably coupled to a distal end of the chassis 120; a tappet 130 extending from the chassis 120 toward the flap 150; and a local controller 112.

The flap 150 is gravitationally biased toward a neutral pitch orientation 114 and includes: a display surface 156 and a rear surface 158, opposite the display surface 156, oriented toward the chassis 120. The flap 150 is configured to pivot about a pivot axis 124 over a range of angular pitch orientations.

The tappet 130 extends from the chassis 120 toward the rear surface 158 of the flap 150 and is configured: to advance toward the rear surface 158 of the flap 150 to angularly displace the flap 150 from the neutral pitch orientation 114; and to retract from the flap 150 to permit the flap 150 to oscillate through the range of angular pitch orientations.

The local controller 112 is configured to trigger an actuator 140 (e.g., a stepper-driven linear actuator) arranged in the chassis 120: to advance the tappet 130 toward the flap 150 to drive the flap 150 toward a target pitch orientation (e.g., from 0° to 85°); and to retract the tappet 130 to separate the tappet 130 from the flap 150.

### 2.1.1 Variation: Independent Display Unit

In one variation, a display unit 110 includes: a flap 150 pivotably coupled to a chassis 120; a tappet 130 extending from the chassis 120 toward the flap 150; and an actuator 140 arranged in the chassis 120.

The flap 150 includes: a display surface 156; and a rear surface 158 opposite the display surface 156. The flap 150 is configured to pivot about a pivot axis 124 over a range of angular pitch orientations.

The tappet 130 is configured: to advance toward the flap 150 to angularly displace the flap 150 from the neutral pitch orientation 114; and to retract from the flap 150 to permit the flap 150 to oscillate through the range of angular pitch orientations.

The actuator 140 is configured: to advance the tappet 130 toward the flap 150 to drive the flap 150 toward a target pitch orientation; and to retract the tappet 130 to separate the tappet 130 from the flap 150.

### 2.1.2 Variation: Induced Pendular Motion

In one variation, the local controller 112 is configured to trigger the actuator 140 to drive the tappet 130 toward the flap 150 at a first velocity: to contact the tappet 130 against the flap 150; and to angularly displace the flap 150 about a pivot axis 124 from the neutral pitch orientation 114 toward the target pitch orientation while maintaining contact between the tappet 130 and the flap 150.

In this variation, the local controller 112 is also configured to trigger the actuator 140 to retract the tappet 130 from the flap 150 at a second velocity greater than the first velocity: to separate the tappet 130 from the flap 150; and to release the flap 150 to oscillate (e.g., as a “pendulum”) about the pivot axis 124 past the neutral pitch orientation 114.

### 3. Applications

Generally, a display system 100 includes a set (or an “array”) of independently-operable display units 110 (e.g., non-binary mechanical “pixels”). In particular, each display unit 110 includes: a chassis 120; a flap 150 (or “physical pixel element”) pivotably coupled to and suspended from the chassis 120 such that the flap 150 can pivot (or oscillate) about a pivot axis 124 on the chassis 120; a tappet 130 arranged on the chassis 120 rearward of the flap 150; an actuator 140 coupled to the tappet 130; and a local controller 112. The local controller 112 can trigger the actuator 140: to advance the tappet 130, initially separated from the flap 150, into contact with the flap 150; to further drive the tappet 130 forward to pivot the flap 150 from a neutral pitch orientation 114 (e.g., 0°) to a target pitch orientation (e.g., 90°); and to retract the tappet 130, such as to separate the tappet 130 from the flap 150 while the flap 150 is pitched forward and release the flap 150 to (freely) oscillate about the pivot axis 124.

Thus, each display unit 110 independently controls angular displacement and release of its flap 150, such that the array of display units 110 generates coordinated yet locally governed motion (e.g., synchronized wave patterns, rippling reflections, or sequential pitch transitions across adjacent display units 110) across a multi-panel display 108 (e.g., a surface collectively defined by visible surfaces of the flaps 150 and visible to a user). In particular, the display unit 110 can actively position the flap 150 at a target pitch orientation and subsequently permit predictable oscillatory motion about the neutral pitch orientation 114, thereby introducing both controlled angular states and transient dynamic states defined by angular position, direction of motion, and angular velocity of the flap 150. Accordingly, the display system 100 includes a distributed array of mechanically driven display elements that generate continuous, non-binary visual variation across the multi-panel display 108.

More specifically, the display unit 110 operates as an independently-operable, non-binary mechanical pixel: with direct positional control between a neutral pitch orientation 114 (e.g., 0°) and a maximum forward pitch orientation (e.g., 95°); with positional control as the flap 150 pitches rearward toward the neutral pitch orientation 114 (e.g., 0°) only when the tappet 130 retracts slower than the natural acceleration of the flap 150 given inertia and resistance in the display unit 110; with absence of positional control as the flap 150 pitches rearward past the neutral pitch orientation 114; and with positional control as the flap 150 pitches forward toward the neutral pitch orientation 114 only when the tappet 130 advances faster than the natural acceleration of the flap 150 given inertia and resistance in the flat unit.

### 3.1 Actuation Phases

In particular, the display unit 110 can include: a flap 150 pivotably coupled to a chassis 120; an actuator 140 (e.g., a stepper-driven linear actuator) coupled to the chassis 120; a tappet 130 longitudinally driven by the actuator 140 along the chassis 120; and a local controller 112 configured to trigger the actuator 140 to drive the tappet 130 based on received or stored actuation instructions. More specifically, the local controller 112 is configured to trigger the actuator 140 to drive the tappet 130 toward the flap 150: to couple to the flap 150; and to pitch the flap 150 forward about the pivot axis 124 from a neutral pitch orientation 114, thereby increasing potential energy of the flap 150. Additionally, the local controller 112 can trigger the actuator 140 to retract the tappet 130 from the flap 150, such as: to separate the tappet 130 from the flap 150; and to release the flap 150 to pivot rearward about the pivot axis 124, thereby transferring potential energy in the flap 150 into kinetic energy as the flap 150 oscillates past the neutral pitch orientation 114.

### 3.2 Mechanical Display: Multi-Unit Assembly

The flap 150 defines an outward-facing display surface 156 exhibiting a set of visual characteristics, such as a surface finish (e.g., matte, polished, or faceted), a color, and/or a particular light reflectivity. Accordingly, the display unit 110 is configured to drive rotation of the flap 150 about a pivot axis 124 over a range of pitch orientations, such as between a forward pitch orientation (e.g., 85°) and a trailing position (e.g., −30°), to alter a visible characteristic presented at the multi-panel display 108 (e.g., to change an angle of reflection, an apparent brightness, or a perceived surface orientation). In one example, as the flap 150 oscillates about the pivot axis 124, the display surface 156 of the flap 150 can reflect ambient light at different angles, thereby producing a time-varying visual effect across the multi-panel display 108 based on optical characteristics of a surface finish of the flap 150.

Furthermore, an array of display units 110 can be installed on a surface 190 (or a “panel”) to form a non-binary, multi-pixel display. For example, a set of display units 110 can be grouped into columns, rows, or clusters, each governed by a column controller 106, each column controller 106 governed by a primary controller 104. In particular, the primary controller 104 can generate and distribute actuation instructions to the column controllers 106 for distribution to its coupled display units 110. Each display unit 110 can then independently execute its assigned actuation instruction to drive angular displacement of its flap 150 according to defined timing parameters in a corresponding instruction.

Each display unit 110 can independently execute unique actuation instructions to produce a defined sequence of pitch orientations over time. The resulting time-varying pitch orientations across the array of display units 110 can be synchronized to form spatial and temporal patterns (e.g., traveling waves, gradients, or pulses) that generate dynamic visual effects based on directional reflection of ambient light from the outward-facing surfaces of the flaps 150 (e.g., shifting highlights, rippling motion, or simulated shading).

### 3.3 Scalable Motion Control

In one application, the primary controller 104 can transmit instructions that specify motion parameters to each display unit 110 (e.g., rather than continuous, explicit actuator-level displacement commands). For example, the primary controller 104 can transmit an instruction to a display unit 110 that specifies a function defining a relationship between angular displacement of the flap 150 and time, a sequence of target pitch orientations defined over a time interval, or a set of parameters defining a motion profile. The display unit 110 can then read and locally execute this instruction.

In one example, the local controller 112 can: receive an instruction assigned to the display unit 110 by the primary controller 104; extract a function, defining a relationship between angular displacement of the flap 150 and time, from the instruction; and derive a target pitch orientation for the flap 150 at a particular time based on the function. The local controller 112 can then execute the instruction by triggering the actuator 140 to longitudinally displace the tappet 130, thereby angularly displacing the flap 150 toward the target pitch orientation.

Accordingly, the primary controller 104 can disseminate instructions to the display units 110 that specify high-level motion definitions, and each display unit 110 can then locally execute the instruction. By disseminating these high-level motion definitions to the display units 110, the display system 100 can reduce communication bandwidth requirements between the primary controller 104 and the display units 110. Therefore, the display system 100 can scale to larger installations that include increased quantities of display units 110 without a proportional increase in communication overhead or centralized computational burden.

### 3.4 Interactive Optical Modulation

In one application, the primary controller 104 can: access a video stream from an optical sensor of the display system 100; detect and track a current position of a user, proximal the display system 100 (e.g., walking adjacent the display system 100), represented the video feed; identify a set of display units 110 within a threshold distance from the current position of the user; and serve a corresponding actuation instruction to the local controllers 112 of the set of display units 110 to uniquely represent the current position of the user relative to the display system 100 through coordinated oscillatory motion of the set of display units 110.

For example, the primary controller 104 can define a set of actuation instructions for the array of display units 110 that: triggers the local controllers 112 of the set of display units 110, within the threshold distance to the user, to produce a defined sequence of pitch orientations; and commands the remaining display units 110 outside of this set of display units 110 to maintain their flaps 150 in the neutral pitch orientation 114. In this example, the primary controller 104 can then serve this set of actuation instructions in real-time to corresponding display units 110. Therefore, the display system 100 can: maintain contextual awareness of a user proximal the display system 100 based on continuous visual input from the optical sensor; and trigger local controllers 112 of display units 110 in real time to produce dynamic visual effects based on position, movement trajectory, or gesture activity of the user relative to the multi-panel display 108.

### 4. Display Unit

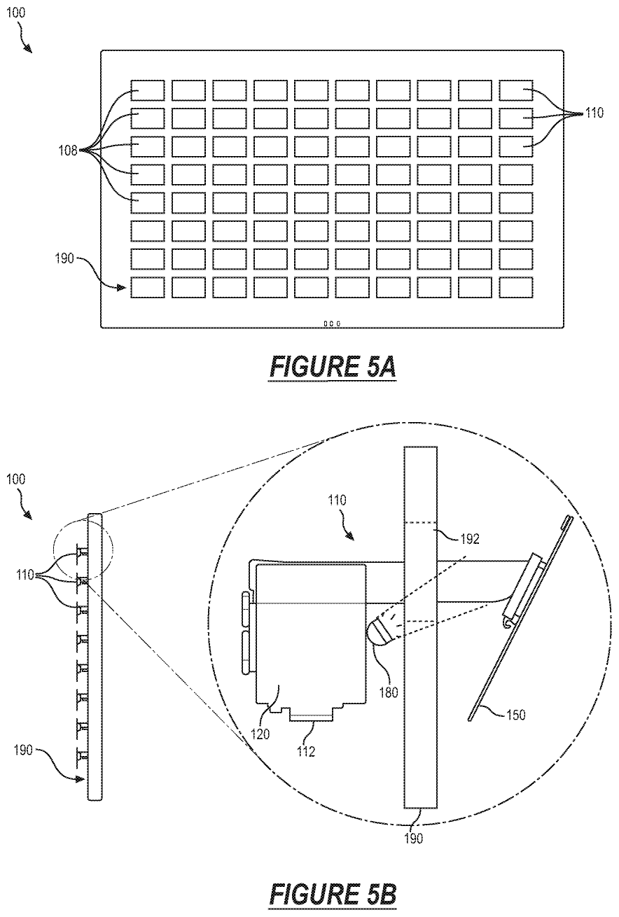

Generally, as shown in FIGS. 1A and 1B, the display unit 110 includes: a chassis 120; a flap 150 pivotably coupled to the chassis 120 and including opposing surfaces that exhibit various visual characteristics (e.g., surface finishes, light reflectivity); a tappet 130 configured to extend and retract from the chassis 120 to contact and rotate the flap 150 through a range of angular pitch orientations; and an actuator 140 configured to drive longitudinal motion of the tappet 130. In particular, the display unit 110 is configured to install on a surface 190 (e.g., a vertical wall) such that a display surface 156 of the flap 150 is exposed on (or defines) a multi-panel display 108 while occupying a neutral (or resting) position, as shown in FIG. 5A.

The actuator 140 is configured to drive the tappet 130 into contact with the flap 150 such that the flap 150 pivots about a pivot interface (e.g., a coupling location with the chassis 120) to alter a visual characteristic presented at the multi-panel display 108. Therefore, the display unit 110 generates a dynamic visual effect by repeatedly driving and releasing the flap 150, such that the flap 150 alternately exposes different surfaces or visual features while oscillating about the pivot axis 124.

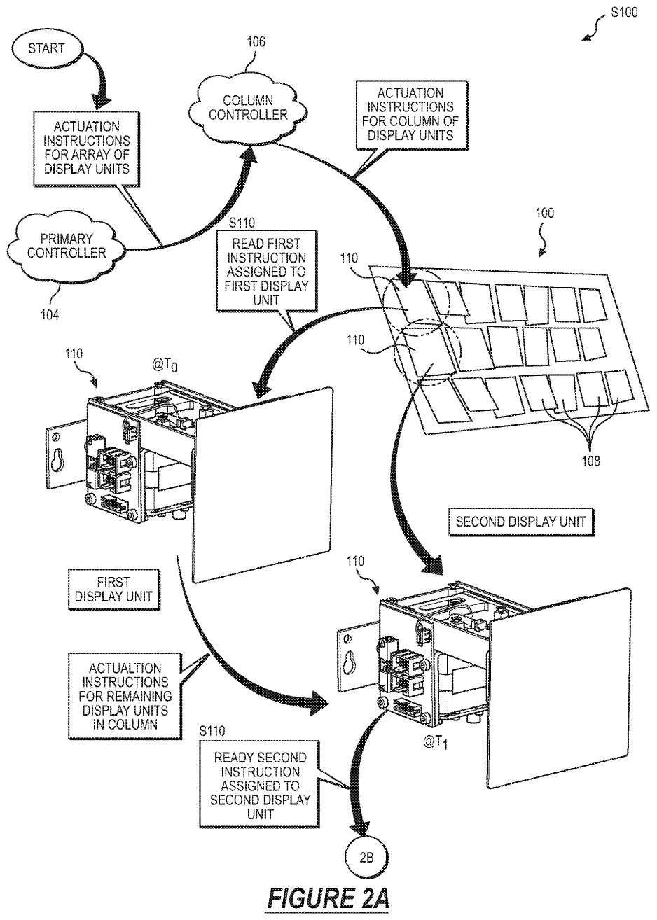

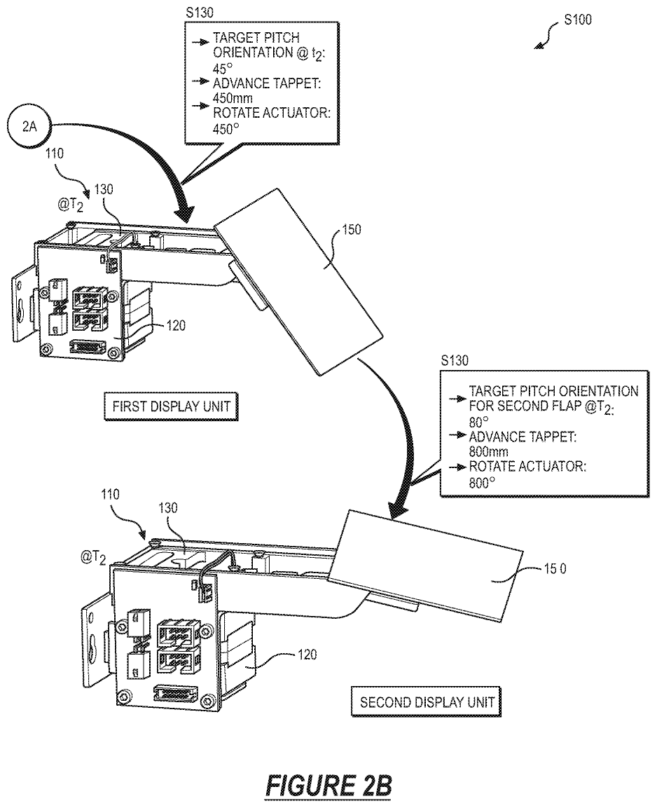

For example, the display unit 110 can be arranged in an array of display units 110 installed on the surface. In this example, each display unit 110 can independently drive a flap 150 to a target pitch orientation at a target time such that the array of display units 110 collectively forms an animated image, pattern, or texture at the multi-panel display 108, as shown in FIG. 2A.

### 5. Chassis

The chassis 120 is configured to mount to the surface and house a set of components of the display unit 110. For example, the chassis 120 can be formed of a material (e.g., a metallic material) such that the chassis 120 defines a rigid structure configured to support the tappet 130, the flap 150, and the actuator 140. In particular, the chassis 120 can define: an actuator 140 mount configured to receive the actuator 140 at a proximal end of the chassis 120; a flap mount configured to pivotably couple the flap 150 to a distal end, opposite the proximal end, of the chassis 120; and a tappet channel configured to couple the tappet 130 to the chassis 120 and to guide longitudinal displacement of the tappet 130 along a longitudinal axis of the chassis 120 (e.g., toward the flap 150). More specifically, the flap mount can define a pivot axis 124 (e.g., a lateral axis) orthogonal to the longitudinal axis of the chassis 120. The flap mount can protrude outwardly from the chassis 120 such that the flap 150, when coupled to the flap mount, can pivot about the pivot axis 124 in both rotational directions (i.e., relative to a neutral pitch orientation 114) during pendular motion.

### 6. Flap

Generally, as shown in FIGS. 1A and 1B, the flap 150: is configured to pivot relative to the chassis 120 about a pivot axis 124; and includes opposing surfaces that exhibit different visual characteristics (e.g., color, pattern, texture, light reflectivity, optical transparency) to alter a visual appearance at the multi-panel display 108. In particular, the flap 150 includes: a backing plate 152 pivotably coupled to a distal end of the chassis 120; and a façade panel 154 configured to couple (e.g., adhesively couple) to the backing plate 152 and (e.g., unitary, thin body) including two opposing surfaces that exhibit various colors, patterns, or textures.

In particular, the flap 150 can be configured to occupy a neutral pitch orientation 114 (e.g., a resting position) absent manipulation via the tappet 130. For example, the flap 150 can rest in a vertical orientation (e.g., at 0°) such that the façade panel 154 is approximately orthogonal to the tappet 130. In this example, the flap 150 can pivot about the pivot axis 124 over a range of pitch orientations forward and rearward of the vertical orientation, such as between approximately 90° forward of the vertical orientation and 30° rearward of the vertical orientation.

In particular, the façade panel 154 includes: a display surface 156; and a rear surface 158, opposite the display surface 156, oriented toward the chassis 120. The backing plate 152 is: coupled to the distal end of the chassis 120 at a pivot interface; and configured to pivot about a pivot axis 124 over a range of angular pitch orientations, responsive to longitudinal displacement of the tappet 130, such as to selectively expose the display surface 156 and the rear surface 158 to the multi-panel display 108 or to manipulate visual characteristics of the façade panel 154 at the multi-panel display 108.

For example, the façade panel 154 can include: a display surface 156 defining a first visual characteristic (e.g., a first color, a first pattern, a first surface finish); and a rear surface 158 defining a second visual characteristic (e.g., different from or similar to the first visual characteristic). Accordingly, the display unit 110 can generate a dynamic visual effect by repeatedly driving and releasing the flap 150, such that the flap 150 alternately exposes the front and rear surfaces 158 (e.g., exhibiting different visual features) while pivoting about the pivot axis 124, as shown in FIG. 2A.

In one example, the façade panel 154 (e.g., a flat, rectangular panel, a curved panel) can include: a display surface 156 (e.g., an outward face) coated with a matte black surface finish; and a rear surface 158 (e.g., an inward face) with a mirror-polished metallic finish. In another example, the façade panel 154 can include: a display surface 156 defining a first light reflectivity; and a rear surface 158 defining a second light reflectivity less than the first light reflectivity. In another example, the façade panel 154 can include: a display surface 156 defining a first optical transparency; and a rear surface 158 defining a second optical transparency less than the first optical transparency.

Furthermore, the flap 150 can be: pivotably coupled to the chassis 120, at the pivot interface, such that a center of mass of the flap 150 is located below the pivot axis 124; and gravitationally biased toward a neutral pitch orientation 114 (e.g., a vertical orientation). In particular, when the tappet 130 retracts and separates from the flap 150, the flap 150 pivots freely about the pivot axis 124 over a range of angular pitch orientations including: pitch orientations forward of the neutral pitch orientation 114; and pitch orientations rearward of the neutral pitch orientation 114. The tappet 130 thus drives the flap 150 in a first rotational direction via contact with the tappet 130, and gravity restores the flap 150 in a second rotational direction (i.e., without additional actuator input).

Accordingly, angular displacement of the flap 150 away from the neutral pitch orientation 114 increases gravitational potential energy of the flap 150. Following retraction of the tappet 130, the flap 150 converts the potential energy into kinetic energy and oscillates about the pivot axis 124 over the range of angular pitch orientations. The flap 150 then passively returns to the neutral pitch orientation 114. The display unit 110 thus drives the flap 150 to a target pitch orientation and subsequently permits passive oscillation and return without continuous actuator input. Thus, the flap 150 restores to the neutral pitch orientation 114 under gravitational bias (e.g., rather than bidirectional actuator-driven reversal) such that the flap 150 reduces control complexity while exhibiting smooth, predictable pendular motion.

In one example, the flap 150 can further include a counterweight 160: arranged proximal the rear surface 158 of the flap 150; and configured to gravitationally bias the flap 150 toward the neutral pitch orientation 113 (e.g., a vertical orientation) while the flap 150 oscillates about the pivot axis 124 (e.g., following retraction of the tappet 130). Additionally, in this example, the counterweight 160 can be configured to locate on the flap over a range of positions to locate the center of mass of the flap 150 at a target offset from the pivot axis 124, the target offset corresponding to a target natural frequency for the flap 150. For example, the counterweight 160 can be coupled to the flap 150 via a fastener configured to vertically translate the counterweight 160 relative to the flap 150 to locate the center of mass of the flap 150 at a target offset from the pivot axis 124.

In one variation, the backing plate 152 defines a contact region configured to contact the tappet 130. The contact region is offset from the pivot axis 124 such that the backing plate 152 and the tappet 130 define a lever arm between a point of applied force and the pivot axis 124. The flap 150 thus converts linear force from the tappet 130 into angular displacement about the pivot axis 124 with increased angular acceleration and reduced actuator torque for a given angular displacement. Accordingly, the flap 150 can pivot toward the target pitch orientation with relatively high angular acceleration due to the reduced distance between the contact region and the pivot axis 124 and the compact mass distribution of the flap 150 about the pivot axis 124. The flap 150 further exhibits predictable swing amplitude and oscillation period governed by the mass distribution of the flap 150 and the vertical offset of the center of mass relative to the pivot axis 124, as discussed below.

### 7. Tappet

The tappet 130: extends longitudinally from the chassis 120 toward the rear surface 158 of the flap 150; and is configured to convert rotational output of the actuator 140 into longitudinal motion that drives angular displacement of the flap 150. In particular, the tappet 130 defines an elongated body: housed within the tappet channel; including a proximal end and a distal end opposite the proximal end; and configured to translate along the tappet channel, relative to the chassis 120, to locate a distal end of the tappet 130 in contact with the flap 150.

In one example, the tappet 130 is configured to couple to the actuator 140 via an elongated slot 134 arranged at the proximal end of the tappet 130. In particular, the elongated slot 134: extends laterally across the tappet 130 (e.g., orthogonal to the longitudinal axis of the chassis 120); and is configured to receive a pin 144 of the actuator 140, the pin 144 configured to laterally displace within the elongated slot 134, responsive to rotation of the actuator 140, to drive longitudinal motion of the tappet 130. More specifically, the elongated slot 134 constrains motion of the pin 144 to a lateral path across the tappet 130 while the tappet 130 is constrained to longitudinal translation within the tappet channel, such that rotation of the actuator 140 produces longitudinal displacement of the tappet 130 along the longitudinal axis of the chassis 120. Accordingly, responsive to rotation of the actuator 140, the tappet 130 can: advance toward the rear surface 158 of the flap 150 to contact the flap 150 and angularly displace the flap 150 from the neutral pitch orientation 114; and retract from the flap 150 to permit the flap 150 to oscillate through the range of angular pitch orientations.

### 7.1 Variation: Damper

In one variation, the tappet 130 further includes a damping element (e.g., an elastomeric pad or compliant insert): arranged at the distal end of the tappet 130; and formed of a material exhibiting energy-absorbing and vibration-damping properties (e.g., an elastomeric material, silicone, polyurethane, thermoplastic elastomer (TPE), rubber, or a material characterized by a Shore A hardness between 20 and 50). In particular, the damping element is configured to contact the backing plate 152 of the flap 150 during advancement of the tappet 130 toward the flap 150 and to compress upon contact with the flap 150, such as to attenuate impact forces transmitted from the tappet 130 to the flap 150 and reduce transmission of high-frequency mechanical vibrations during impact.

In another variation, the flap 150 can include a damping element arranged proximal the contact region of the flap 150. In this variation, the damping element arranged on the flap 150 is configured to compress responsive to contact with the distal end of the tappet 130 and to dissipate impact energy prior to transmission through the backing plate 152, thereby reducing structural vibration of the flap 150 during impact. Accordingly, the tappet 130 can be configured to engage the flap 150 with reduced mechanical shock while maintaining sufficient force transfer to angularly displace the flap 150 toward the target pitch orientation. Therefore, the tappet 130 reduces mechanical noise and limits excitation of unintended oscillatory modes of the flap 150 during repeated actuation cycles.

### 7.2 Variation: Spring Element

In one variation, the tappet 130 further includes a spring element arranged at the distal end of the tappet 130. The spring element is configured to compress during engagement between the tappet 130 and the flap 150 and to store mechanical energy transferred from the actuator 140 through the tappet 130. In particular, compression of the spring element during contact with the flap 150 preserves mechanical energy that may otherwise dissipate during impact and releases this stored mechanical energy into the flap 150, such as to increase momentum transfer to the flap 150 during angular displacement.

In another variation, the flap 150 includes a spring element arranged at the contact region on the rear surface 158 of the flap 150. In this variation, the spring element is configured to compress responsive to contact with the distal end of the tappet 130 and to release stored mechanical energy into the flap 150 during angular displacement of the flap 150 about the pivot axis 124. In one example, the spring element can include a compression spring press-fit within a receptacle at the contact region and oriented toward the tappet 130. For example, the spring element can define a free length of 4 millimeters, a compressed length of 2 millimeters, and a spring constant of 0.35 Newtons per millimeter. Accordingly, the spring element increases efficiency of mechanical energy transfer between the tappet 130 and the flap 150 while reducing impact losses during engagement. Thus, in this variation, the tappet 130 can be configured to increase angular acceleration of the flap 150 during angular displacement without increasing actuator torque.

### 7.3 Variation: Magnetic Element

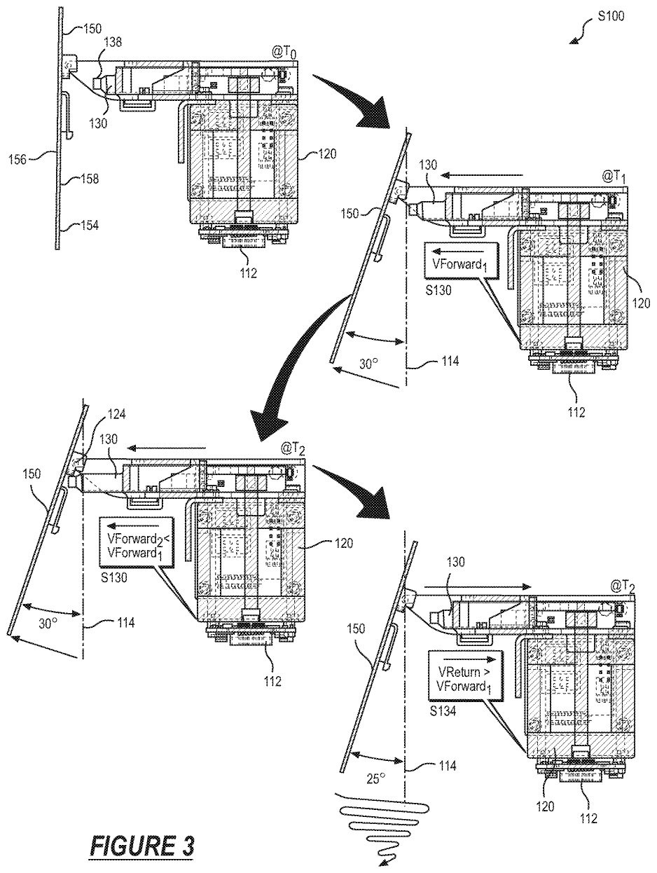

In one variation, as shown in FIG. 3, the tappet 130 further includes a magnetic element 138: arranged proximal a distal end of the tappet 130; and configured to magnetically couple the flap 150 to the tappet 130 (e.g., via a ferrous element located on the flap 150). In particular, the magnetic element 138 generates a magnetic coupling force that resists incidental separation between the tappet 130 and the flap 150 during engagement such that separation occurs responsive to intentional retraction of the tappet 130 by the actuator 140. More specifically, the magnetic element 138 is configured: to maintain magnetic coupling with the flap 150 when the tappet 130 is retracted from the flap 150 at retraction velocities less than a threshold velocity; and to magnetically decouple from the flap 150 when the tappet 130 is retracted from the flap 150 at retraction velocities greater than the threshold velocity. For example, the actuator 140 can: retract the tappet 130 at a retraction velocity that gradually overcomes the magnetic coupling force; or rapidly retract the tappet 130 to apply a mechanical impulse that abruptly overcomes the magnetic coupling force between the tappet 130 and the flap 150 (i.e., to initiate free pendular motion of the flap 150).

Accordingly, by magnetically coupling the tappet 130 to the flap 150 during advancement and selectively decoupling the tappet 130 from the flap 150 responsive to a retraction velocity exceeding a threshold velocity, the display unit 110 can: shape angular displacement of the flap 150 during actuation while preserving unconstrained pendular motion of the flap 150 following separation; suppress rebound by momentarily resisting separation during initial contact between the tappet 130 and the flap 150; and control transfer of momentum to the flap 150 without implementing a rigid mechanical linkage between the actuator 140 and the flap 150. However, the tappet 130 can be mechanically coupled to the flap 150 via any mechanism such that the actuator 140 drives angular displacement of the flap 150 in both a forward direction and a return direction (e.g., without relying on gravitational bias).

In another variation, the display unit 110 includes: a primary magnetic element 138 arranged at the contact region of the flap 150; and a secondary magnetic element 138 arranged at the distal end of the tappet 130 and exhibiting a polarity selected to generate a magnetic repelling force relative to the primary magnetic element 138. In this variation, advancement of the tappet 130 toward the flap 150 generates a magnetic repelling force between the primary magnetic element 138 and the secondary magnetic element 138 without physical contact between the tappet 130 and the flap 150. In particular, this magnetic repelling force applies a torque to the flap 150 about the pivot axis 124 to initiate angular displacement of the flap 150. The actuator 140 can then retract the tappet 130 to reduce the magnetic repelling force and permit free rotational motion of the flap 150 about the pivot axis 124. Thus, in this variation, the flap 150 can pivot about the pivot axis 124 without mechanical impact between the tappet 130 and the flap 150, thereby reducing mechanical wear and impact-induced vibration while preserving pendular motion of the flap 150.

### 8. Drive System

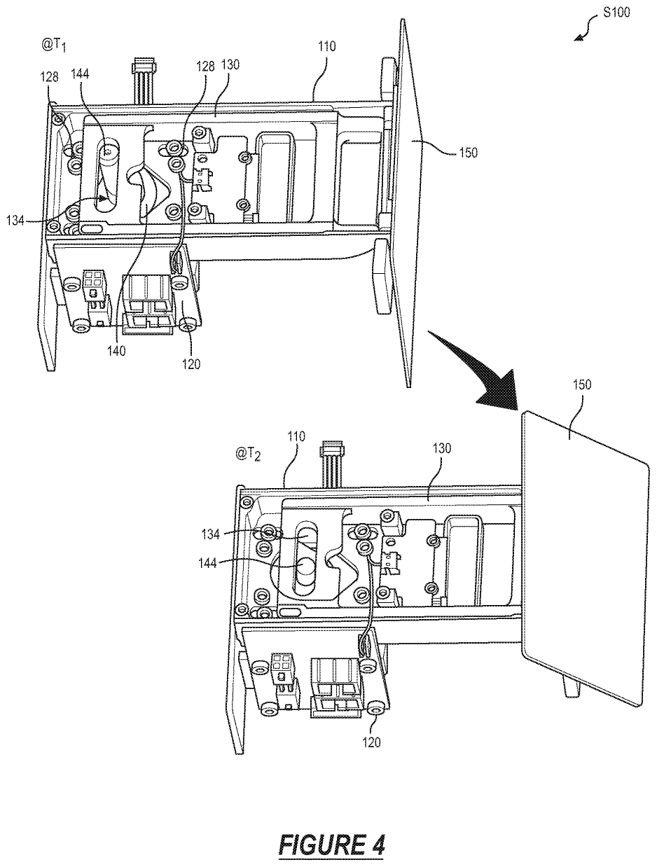

The actuator 140 (e.g., a stepper motor, a servo motor, a brushed or brushless direct-current motor) can install on the chassis 120 at the actuator 140 mount and advance and retract the tappet 130 relative to the flap 150. In particular, as shown in FIG. 4, the actuator 140 is configured to advance the tappet 130 in a first direction toward the flap 150: to locate the tappet 130 in contact with the flap 150; and to angularly displace the flap 150 toward the target pitch orientation (i.e., to increase gravitational potential energy of the flap 150). The actuator 140 is further configured to retract the tappet 130 in a second direction to separate the tappet 130 from the flap 150. For example, the actuator 140 can retract the tappet 130 to a position rearward of the neutral pitch orientation 114 of the flap 150 such that the flap 150 can: oscillate through pitch orientations located rearward of the neutral pitch orientation 114; and passively restore to the neutral pitch orientation 114.

In one example, the actuator 140 includes a pin 144: coupled to an output shaft of the actuator 140; and configured to engage the elongated slot 134 of the tappet 130. In particular, the actuator 140 is configured to rotate the pin 144 about an actuator axis. More specifically, as the output shaft rotates, the pin 144 travels along a circular path about the actuator axis and engages opposing sidewalls of the elongated slot 134. The elongated slot 134 extends laterally across the tappet 130, and the tappet 130 is constrained to longitudinal translation within the tappet channel along the longitudinal axis of the chassis 120. Thus, the interaction between the circular motion of the pin 144 and the lateral orientation of the elongated slot 134 constrains the pin 144 to lateral displacement relative to the tappet 130 while the tappet 130 translates longitudinally within the chassis 120, thereby converting rotational motion of the output shaft into longitudinal displacement of the tappet 130. More specifically, the pin 144 laterally displaces within the elongated slot 134 while exerting a longitudinal force component on the tappet 130, thereby driving advancement or retraction of the tappet 130 (e.g., depending on direction of rotation of the output shaft). Thus, in this example, the actuator 140 is configured to rotate the output shaft: to drive lateral displacement of the pin 144 within the elongated slot 134; to drive longitudinal displacement of the tappet 130; and to drive angular displacement of the flap 150.

In one variation, the actuator 140 (e.g., a linear actuator) is configured to extend and retract the tappet 130 along a guide axis relative to the chassis 120 to drive angular displacement of the flap 150 about the pivot axis 124. In another variation, the display unit 110 can further include a rotary encoder coupled to the actuator 140, such as a rotary optical encoder configured to output “ticks” in response to orientation changes of the actuator 140. Alternatively, the rotary encoder can be coupled to the flap 150 and configured to output ticks in response to angular displacement of the flap 150 about the pivot axis 124.

### 8.1 Adjustable Actuator Mount

In one variation, the chassis 120 includes a mounting slot 128 (or a set of mounting slots 128) configured: to couple the actuator 140 to the chassis 120; and to locate the actuator 140 over a range of longitudinal positions relative to the flap 150. In particular, the actuator 140 is configured to mount to the chassis 120 via the mounting slot 128 at a particular longitudinal position that locates an output shaft of the actuator 140 at a target distance from the pivot axis 124 of the flap 150. More specifically, the distance between the actuator axis and the pivot axis 124 defines a geometric relationship that influences: timing of contact between the tappet 130 and the flap 150; magnitude of angular displacement achieved for a given stroke of the tappet 130; and phase alignment between tappet advancement and flap oscillatory motion. Thus, variations in the relative positions of the actuator axis and the pivot axis 124 across display units 110 in an array can result in inconsistent contact timing, inconsistent angular acceleration, and non-uniform pendular behavior between adjacent display units 110.

Accordingly, the mounting slot 128 (or set of mounting slots 128) permits longitudinal adjustment of the actuator 140 relative to the pivot axis 124, such as to compensate for manufacturing tolerances, display system 100 tolerances, or structural variations between display units 110, to achieve consistent angular displacement profiles and consistent oscillatory behavior across an array of display units 110. Therefore, the display unit 110 maintains uniform visual motion characteristics across multiple units without requiring individualized control tuning for each actuator 140.

### 9. Local Controller

Generally, the local controller 112 includes an internal clock and local memory and is configured to control actuation of the display unit 110 by triggering the actuator 140 to advance and retract the tappet 130, relative to the flap 150, based on instructions assigned to the display unit 110. As described below, the local controller 112 stores an actuation instruction and executes the actuation instruction to drive the actuator 140 through a sequence of commands corresponding to changes in longitudinal position of the tappet 130 along the chassis 120. In particular, based on timing and positional parameters defined in an instruction, the local controller 112 can trigger the actuator 140: to advance the tappet 130 toward the flap 150 to drive the flap 150 toward a target pitch orientation; and to retract the tappet 130 to separate the tappet 130 from the flap 150.

### 10. Column Controller and Primary Controller

As shown in FIGS. 2A and 2B, the display system 100 can include an array of display units 110 that includes columns (or rows, or clusters) of display units 110 connected (e.g., in parallel or in series) to a column controller 106, each column controller 106 connected (e.g., in parallel or in series) to a primary controller 104. The primary controller 104 can coordinate timing, synchronization, and distribution of actuation instructions across multiple column controllers. In particular, a column controller 106 can: be located between a column or cluster of display units 110, the primary controller 104, and a power supply; distribute power to the connected display units 110; receive actuation instructions and timing triggers from the primary controller 104; and transmit these routines and triggers to the local controllers 112 of the corresponding display units 110 within that column or cluster.

In one example, display units 110 in a column (or cluster) can be connected in series (or “daisy-chained” together) such that a primary display unit 110 in the column is connected to, or functions as, the column controller 106. In this configuration, the column controller 106 (or primary display unit 110) receives a set of actuation instructions(e.g., ordered from the bottom to the top of the column) from the primary controller 104 and transmits the full set to the primary display unit 110 in the column. upon receipt, the primary display unit 110 extracts the primary actuation instruction from the set and forwards the remaining ordered routines to a secondary display unit 110 in the column. The secondary display unit 110 then extracts the primary routine from the remaining set and passes the rest to the next display unit 110 in the column. This process continues sequentially along the column such that actuation instructions can be distributed along the column without requiring unique identifiers for individual display units 110.

### 11. Actuation Instructions

Generally, the display unit 110 is configured: to receive an actuation instruction that specifies motion parameters (e.g., a target pitch orientation; a target time; a motion profile; or a sequence of pitch orientations over time) for maneuvering the flap 150; and to drive the flap 150 according to the actuation instruction to alter a visual characteristic presented at the multi-panel display 108.

In one implementation, an array of display units 110 can cooperate with a computer system to generate actuation instructions corresponding to a visual routine. In particular, the computer system generates a set of actuation instructions corresponding to a particular action routine and assigns individual instructions to respective display units 110 within the array of display units 110. The computer system (or the primary controller 104) then disseminates the actuation instructions to the display units 110 for execution. Each display unit 110 then reads an assigned actuation instruction and triggers the actuator 140 to drive the flap 150 toward a corresponding target pitch orientation according to timing defined in the actuation instruction such that the array of display units 110 collectively forms an animated image, pattern, or texture at the multi-panel display 108.

In one implementation, the computer system can implement methods and techniques described in U.S. patent application Ser. No. 17/067,117, filed on 9 Oct. 2020, which is incorporated in its entirety by this reference, to generate a set of actuation instructions for the display unit 110 (or the array of display units 110). For example, the computer system can implement methods and techniques described in U.S. patent application Ser. No. 17/067,117: to receive a geometry of an array of display units 110 (e.g., a quantity of display unit columns, a quantity of display unit rows, a width and height of each display unit 110, and/or a pitch height and pitch width between adjacent display unit); to receive a video including a sequence of frames, such as a video uploaded by a user; to process the video to conform to the geometry of the array of display units 110, such as by cropping or adjusting the video to an aspect ratio (i.e., a width to height ratio) equal to an aspect ratio of the array of display units 110; and to transform visual data, extracted from the processed video, into a time-ordered sequence of motion parameters for each display unit 110 such that pitch orientations of the flaps 150 vary over time to represent the video content across the array of display units 110.

In another example, the computer system can: receive a still image or a sequence of still images; process each still image to conform to the geometry of the array of display units 110; and, for each display unit 110, derive a corresponding pitch orientation and dwell time representing a visual state derived from the still image. The computer system then compiles a sequence of pitch orientations and associated dwell times into an actuation instruction for each display unit 110.

In another example, the computer system retrieves a predefined motion pattern (e.g., a wave pattern, ripple pattern, shimmer pattern, or other dynamic routine) and maps the predefined motion pattern to pitch orientations of individual display units 110 based on the geometry of the array of display units 110. The computer system assigns timing parameters corresponding to a selected speed and duration of the predefined motion pattern and generates corresponding actuation instructions for the display units 110.

### 11.1 Actuation Instruction Contents

In one implementation, the computer system (or the primary controller 104) can disseminate the set of actuation instructions to the display units 110 for execution. In one example, the primary controller 104 (or the computer system) can disseminate an actuation instruction to a display unit 110 that specifies sequences of: target pitch orientations (e.g., 32-bit representations of angular offsets in degrees from the neutral pitch orientation 114) for the flap 150; relative pitch orientations (e.g., 32-bit representations of angular offsets from a last angular pitch orientations occupied by the flap 150) for the flap 150; angular speeds; angular accelerations; angular decelerations; directions of angular motion; absolute or relative “stop and go” positions; durations of continuous motion periods; durations of stop and go intervals; and/or motion profiles containing the foregoing parameters and spanning durations of time (e.g., multiple seconds, minutes, or hours).

For example, the computer system can generate an actuation instruction in the form of a single “frame,” which can be uploaded to the primary controller 104 and distributed to a corresponding local controller of a particular display unit (e.g., via a column controller 106). The display unit 110 can then load this actuation instruction and execute angular positions, speeds, and accelerations over periods of time specified in this actuation instruction independently of other display units 110 in the display system 100 concurrently executing their own stored actuation instructions. For example, each display unit 110 can execute an assigned actuation instruction independently of each other display unit over a period of minutes or hours based on an internal clock (e.g., a quartz clock) in the display unit 110 and then time-synchronize itself to the primary controller 104 (and thus other display units 110 in the display system 100) only after loading a new actuation instruction minutes or hours later (or only upon receipt of a command to repeat the loaded actuation instruction from the primary controller 104 some minutes or hours later).

### 12. Operation

Blocks of the method S100 recite, at a display unit 110: receiving an instruction assigned to the display unit 110 by a primary controller 104 in Block S110; based on the instruction, deriving a target pitch orientation for angularly displacing a flap 150, pivotably coupled to a chassis 120 of the display unit 110, at a particular time in Block S120; via an actuator 140 of the display unit 110, advancing a tappet 130, interposed between the chassis 120 and the flap 150, toward the flap 150 to locate the tappet 130 in contact with the flap 150 and angularly displace the flap 150 from a neutral pitch orientation 114 toward the target pitch orientation at the time in Block S130; and, via the actuator 140, retracting the tappet 130 from the flap 150 to separate the tappet 130 from the flap 150 and permit the flap 150 to oscillate in Block S134.

Generally, the primary controller 104 (and/or a set of column controllers 106) can cooperate with the computer system to disseminate a set of actuation instructions to each display unit 110 in the display system (e.g., an array of display units 110). For example, the primary controller 104 can then distribute these actuation instructions to column controllers 106 of the display system 100, these column controllers 106 can disperse these actuation instructions to their connected display units 110, and each display unit 110 can store its actuation instruction in local memory. In one variation, once these actuation instructions are loaded onto their corresponding display units 110, the primary controller 104 and column controllers 106 can distribute start commands to these display units 110, such as responsive to receipt of a command to begin operation (e.g., via a physical button on the primary controller 104 or via the user portal executing on the computing device connected to the primary controller 104).

In one implementation, a display unit 110 can: receive an instruction assigned to the display unit 110 (e.g., by the primary controller 104); and read motion parameters (e.g., a target pitch orientation for the flap 150 at a particular time, a motion profile) from the instruction. Then, the display unit 110 can execute the instruction by driving the flap 150 according to the motion parameters defined in the instruction (e.g., responsive to receipt of a start command). In particular, the local controller 112 of the display unit 110 can: identify or derive a target pitch orientation for angularly displacing the flap 150 based on the instruction; calculate a target longitudinal displacement for driving the tappet 130 to locate the flap 150 in the target pitch orientation; and trigger the actuator 140 to advance the tappet 130 toward the flap 150 according to the target longitudinal displacement.

More specifically, gravitational bias about the pivot axis 124 maintains the flap 150 at the neutral pitch orientation 114 (e.g., a known angular position relative to the chassis 120) such that the tappet 130 is separated from the flap 150 by a known longitudinal offset. Accordingly, the local controller 112 can: calculate the target longitudinal displacement required to locate the flap 150 in the target pitch orientation based on this known longitudinal offset and a relationship between longitudinal displacement of the tappet 130 and angular displacement of the flap 150 about the pivot axis 124; and calculate a target rotational displacement of the output shaft that achieves the target longitudinal displacement of the tappet 130 corresponding to the target pitch orientation of the flap 150. Then, the local controller 112 can trigger the actuator 140 to rotate according to the target rotational displacement to: longitudinally displace (i.e., advance) the tappet 130 by the target longitudinal displacement; and locate the flap 150 in the target pitch orientation at a target time defined in the instruction. Following displacement of the flap 150 toward the target pitch orientation, the local controller 112 can trigger the actuator 140 to retract the tappet 130.

In one implementation, the local controller 112 can selectively trigger the actuator 140 to advance and retract the tappet 130 (e.g., at a particular velocity) based on motion parameters defined in the actuation instruction, as described below. For example, the local controller 112 can trigger the actuator 140 to: advance the tappet 130 toward the flap 150 such that the tappet 130 maintains contact with the flap 150 while driving angular displacement of the flap 150 about the pivot axis 124; and retract the tappet 130 from the flap 150 such that the tappet 130 maintains contact with the flap 150 while constraining angular displacement of the flap 150 during return motion. Alternatively, the local controller 112 can trigger the actuator 140 to: advance the tappet 130 toward the flap 150 such that the tappet 130 contacts the flap 150 and drives angular displacement of the flap 150; and retract the tappet 130 from the flap 150 such that the tappet 130 separates from the flap 150 to permit the flap 150 to freely oscillate about the pivot axis 124. Thus, the local controller 112 can trigger the actuator 140 to maneuver the tappet 130 to selectively maintain or release contact between the tappet 130 and the flap 150 based on motion parameters specified in the actuation instruction.

The local controller 112 can repeat the foregoing process: to derive a next target pitch orientation based on the actuation instruction; and to trigger rotation of the actuator 140 output shaft to generate a corresponding longitudinal displacement of the tappet 130. Upon reaching the conclusion of the actuation instruction, the local controller 112 can trigger the actuator 140 to retract the tappet 130 to a position rearward of the neutral pitch orientation 114 such that the flap 150 restores to the neutral pitch orientation 114 under gravitational bias without interference from the tappet 130.

Additionally or alternatively, upon reaching the conclusion of the actuation instruction, the local controller 112 can also return confirmation of the actuation instruction to the column controller 106, which can then return confirmation to the primary controller 104. Upon receipt of confirmation from all display units 110, the primary controller 104 and column controllers 106 can repeat the foregoing processes to distribute next actuation instructions to the display units 110 and to trigger execution of these actuation instructions by these display units 110.

In one variation, rather than upload an actuation instruction that includes motion parameters for the flap 150 that spans multiple actuation cycles, the primary controller 104 can: ingest a live or prerecorded stream of frames (e.g., a live video feed from a connected camera); implement methods and techniques described above to transform the stream of frames into time-based motion parameters for each display unit 110 based on a geometry of the array of display units 110; and stream these motion parameters to the column controllers 106, which then stream these grayscale values or target angular positions to their connected display units 110. In this variation, each display unit 110 can then implement the foregoing methods and techniques: to automatically derive target longitudinal displacements of the tappet 130 from the streamed motion parameters; and to continuously drive the actuator 140 to locate the flap 150 in successive target pitch orientations.

In one example, a display surface 156 of a flap 150 exhibits a first color and a portion of the panel (e.g., a front side) exhibits a second color different from the first color. In this example, the flap 150 and the portion of the panel cooperate to define a pixel exhibiting a continuous grayscale transition between the first color and the second color. For example, the local controller 112 can: access an instruction specifying a first grayscale value; trigger the actuator 140 to drive the tappet 130 to angularly displace the flap 150 to a target pitch orientation to yield the first grayscale value; and trigger the actuator 140 to retract the tappet 130 to release the flap 150 to oscillate between the first grayscale value and a second grayscale value.

### 12.1 Target Pitch Orientation

In one variation, a local controller 112 of a display unit 110 can: access an instruction assigned to the display unit 110; and read a target pitch orientation, for the display unit 110 to locate a flap 150 of the display unit 110 at a future time, from the instruction. The local controller 112 can then implement methods and techniques described above to: calculate a target longitudinal displacement for the tappet 130 to angularly displace the flap 150 from a current pitch orientation toward the target pitch orientation; and calculate a target rotational displacement for the actuator 140 that corresponds to the target longitudinal displacement for the tappet 130.

The local controller 112 can then trigger the actuator 140 to rotate according to the target rotational displacement, such as responsive to receiving the start command (or responsive to receiving the actuation instruction, receipt of which by the local controller 112 represents a “start command”). The local controller 112 can then repeat the foregoing process to identify subsequent target pitch orientations defined in the same instruction and to calculate corresponding target rotational displacements according to timing parameters defined in the instruction. Alternatively, in response to conclusion of an actuation instruction assigned to the display unit 110, the local controller 112 can: trigger the actuator 140 to retract the tappet 130; and return confirmation of conclusion of the actuation instruction to the primary controller 104 (e.g., via the column controller 106).

In one example, the primary controller 104 can then issue a second actuation instruction to the display unit 110 and transmit a second start command to the display unit 110 and to other display units 110, via their connected column controllers 106, to initiate execution of their assigned actuation instructions. The local controller 112 can then repeat the foregoing process to execute the second actuation instruction. Thus, in this variation, a local controller 112 of a display unit 110 drives the actuator 140 and the flap 150 of the display unit 110 through a sequence of angular pitch orientations defined in an actuation instruction assigned to the display unit 110 and received from the primary controller 104.

### 12.2 Pitch Orientation as a Function of Time

In one variation, a local controller 112 of a display unit 110 can: access an instruction assigned to the display unit 110; read a function, defining a relationship between angular displacement of the flap 150 and time, from the instruction; and derive a target pitch orientation for the flap 150 at a particular time based on the function. In particular, the function can define angular displacement of the flap 150 as a continuous or discrete function of time over an actuation interval. The local controller 112 can thus evaluate the function at a current time to derive a corresponding target pitch orientation for the flap 150 and then implement methods and techniques described above to: calculate a target longitudinal displacement for the tappet 130 corresponding to the target pitch orientation; and calculate a target rotational displacement for the actuator 140 corresponding to the target longitudinal displacement.

For example, the function can define angular displacement of the flap 150 as a sinusoidal function of time over a defined interval. In this example, the local controller 112 can: derive a first target pitch orientation (e.g., 25° forward of the neutral pitch orientation 114) for a first time based on the first time and the function; and trigger the actuator 140 to advance the tappet 130 toward the backing plate 152 to drive the façade panel 154 toward the first target pitch orientation, such as to expose the display surface 156 of the façade panel 154 (e.g., exhibiting a first color or surface finish) to the multi-panel display 108 at the first time. The local controller 112 can then: derive a second target pitch orientation (e.g., 40° forward of the neutral pitch orientation 114) for a second time subsequent the first time based on the second time and the function; and trigger the actuator 140 to advance the tappet 130 to drive the façade panel 154 toward the second target pitch orientation at the second time, such as to expose the rear surface 158 of the façade panel 154 (e.g., exhibiting a second color or surface finish) to the multi-panel display 108 at the second time.

Thus, in this variation, the local controller 112 derives successive target pitch orientations from a time-based function without receiving discrete target pitch orientations for each time increment, such as to reduce communication bandwidth between the primary controller 104 and the display unit 110.

### 13. Controlled Forward+Uncontrolled Return

In one implementation, the local controller 112 can trigger the actuator 140 to: advance the tappet 130 toward the flap 150 such that the tappet 130 maintains contact with the flap 150 while driving angular displacement of the flap 150 about the pivot axis 124; and retract the tappet 130 from the flap 150 such that the tappet 130 separates from the flap 150 to permit the flap 150 to freely oscillate about the pivot axis 124. In particular, in this implementation, the local controller 112 can trigger the actuator 140 to drive the tappet 130 toward the flap 150 at a first velocity (e.g., 20 millimeters per second) to: contact the tappet 130 against the flap 150; and rotate the flap 150 about the pivot axis 124 from a neutral pitch orientation 114 (e.g., 0°) to a target pitch orientation (e.g., 90°) while maintaining contact between the tappet 130 and the flap 150. More specifically, as the flap 150 rotates about the pivot axis 124, the center of mass of the flap 150 traces an upward arc relative to the pivot axis 124, thereby increasing a vertical height of the center of mass and increasing gravitational potential energy of the flap 150 (e.g., proportional to the angular displacement of the flap 150).

Then, the local controller 112 can trigger the actuator 140 to retract the tappet 130 to separate the tappet 130 from the flap 150. In particular, the local controller 112 can trigger the actuator 140 to drive the tappet 130 away from the flap 150 at a second velocity (e.g., 30 millimeters per second) greater than the first velocity (e.g., 20 millimeters per second) such that the tappet 130 separates from the flap 150 to induce pendulum motion of the flap 150 about the pivot axis 124. More specifically, as the flap 150 rotates downward, potential energy accumulated during angular displacement is converted into angular momentum, and the center of mass follows a descending arc relative to the pivot axis 124 as gravitational torque accelerates the flap 150 toward the neutral pitch orientation 114. Furthermore, following this initial swing, the flap 150 oscillates about the neutral pitch orientation 114 with decreasing amplitude until angular momentum is dissipated and the flap 150 settles at the neutral pitch orientation 114 under the influence of gravity.

Therefore, the local controller 112 can trigger the actuator 140 to advance and retract the tappet 130 at different velocities: to maintain controlled angular displacement of the flap 150 toward the target pitch orientation; and to induce uncontrolled pendular motion of the flap 150 about the neutral pitch orientation 114, such as to generate dynamic visual effects (e.g., shifting specular reflections, rhythmic light scattering, or transient changes in surface visibility) across the flap 150.

### 13.1 Characterization of Flap Oscillation

In one variation, the local controller 112 can: access characteristics of the flap 150 (e.g., mass distribution, center of mass offset from the pivot axis 124, rotational inertia, and damping coefficient); access a mass distribution of the flap 150; access a center-of-mass offset of the flap 150 relative to the pivot axis 124; and calculate a natural frequency of oscillation of the flap 150 based on these characteristics. For example, the local controller 112 can access: an offset between the center of mass of the flap 150 and the pivot axis 124; a mass of the flap 150; a moment of inertia of the flap 150 about the pivot axis 124; and a damping coefficient associated with rotation of the flap 150 about the pivot axis 124. The local controller 112 can then calculate the natural frequency of the flap 150 based on a function correlating the center-of-mass offset of the flap 150, the mass of the flap 150, and the rotational inertia of the flap 150 about the pivot axis 124.

In another variation, the local controller 112 can characterize oscillatory behavior of the flap 150 during the uncontrolled oscillation of the flap 150 about the pivot axis 124. In particular, the local controller 112 can: access characteristics of the flap 150 (e.g., mass distribution, center of mass offset from the pivot axis 124, rotational inertia, and damping coefficient); access a known angular displacement of the flap 150 about the pivot axis 124; and derive a time-domain function that represents oscillatory pitch orientation of the flap 150 as a function of time following tappet disengagement. Thus, the local controller 112 can characterize oscillatory behavior of the flap 150, such as: to predict an angular position of the flap 150 at a future time (e.g., prior to re-engagement with the tappet 130); and/or to predict when the flap 150 passively settles in the neutral pitch orientation 114.

### 13.2 Interception of Oscillating Flap

In one variation, Blocks of the method S100 recite, at a display unit 110: via an actuator 140 of the display unit 110, advancing a tappet 130 toward the flap 150 to locate the tappet 130 in contact with the flap 150 and angularly displace the flap 150 toward a first target pitch orientation at a first time in Block S130; calculating a second pitch orientation of the flap 150 at a second time, following the first time, based on the first target pitch orientation, a difference between the first time and the second time, and a natural frequency of the flap 150 in Block S150; and, via the actuator 140, advancing the tappet 130 toward the flap 150 to angularly displace the flap 150 from the second pitch orientation toward a third target pitch orientation at the second time in Block S130.

In this variation, the local controller 112 can derive an oscillation period for permitting the flap 150 to oscillate about the pivot axis 124 without actuator 140 interference following retraction and separation of the tappet 130 from the flap 150. In particular, the actuation instruction can define a motion profile that includes a defined interval during which the flap 150 is permitted to oscillate without further actuator-driven displacement (e.g., to achieve a desired visual effect).

In particular, in this variation, the local controller 112 can implement methods and techniques described above to trigger the actuator 140 to advance the tappet 130 and locate the flap 150 in a first target pitch orientation at a first time and retract the tappet 130 to separate the tappet 130 from the flap 150 to permit the flap 150 to oscillate about the pivot axis 124. The local controller 112 can then derive an oscillation period, succeeding the first time, for the flap 150 to passively restore toward the neutral pitch orientation 114 based on: a sequence of target pitch orientations for the flap 150 specified in the actuation instruction; and the natural frequency of the flap 150. More specifically, the local controller 112 can predict angular position of the flap 150 during free oscillation based on the first target pitch orientation and the natural frequency of the flap 150. The local controller 112 can then: retrieve subsequent target pitch orientations specified in the actuation instruction; and predict when oscillatory motion of the flap 150 will intersect or approximate a subsequent target pitch orientation without additional actuator-driven displacement. Then, during the oscillation period, the local controller 112 can withhold advancement of the tappet 130 toward the flap 150 to permit free oscillation of the flap 150 under gravitational bias.

Additionally, the local controller 112 can calculate when oscillatory motion of the flap 150 decays to within a defined tolerance of the subsequent target pitch orientation (or when a phase of oscillatory motion aligns with a target direction of displacement). The local controller 112 can derive a future time at which advancement of the tappet 130 will reinforce or redirect motion of the flap 150 toward the third target pitch orientation. The local controller 112 can then trigger the actuator 140 to advance the tappet 130 toward the flap 150 to angularly displace the flap 150 to the second target pitch orientation at the second time. Therefore, the display unit 110 predicts oscillatory motion of the flap 150 based on the natural frequency of the flap 150 and selectively re-engages the flap 150 to maintain alignment with the actuation instruction without continuously driving the flap 150 through each intermediate pitch orientation.

In another variation, the local controller 112 can predict a particular pitch orientation of the flap 150 at a particular time during uncontrolled oscillation of the flap 150 about the pivot axis 124; and drive the tappet 130 toward the flap 150 such that the tappet 130 intercepts (or contacts) the flap 150 at the predicted pitch orientation at the particular time. In particular, in this variation, the local controller 112 can calculate a second pitch orientation of the flap 150 at a second time, following the first time, based on: the first target pitch orientation; a difference between the first time and the second time; a natural frequency of the flap 150; and/or known characteristics of the flap 150 (e.g., a damping coefficient of the flap 150). More specifically, the local controller 112 can predict pitch orientations of the flap 150 over time based on the natural frequency of the flap 150 and an initial pitch orientation at separation of the tappet 130 from the flap 150.

Additionally, based on the second pitch orientation, the local controller 112 can derive a target longitudinal position for the tappet 130 to contact the flap 150 at the second time while the flap 150 oscillates through the range of angular pitch orientations. Furthermore, the local controller 112 can derive a third target pitch orientation for angularly displacing the flap 150 at the second time based on a sequence of target pitch orientations for the flap 150 specified in the actuation instruction. The local controller 112 can then trigger the actuator 140 to drive the tappet 130 toward the target longitudinal position at the second time to angularly displace the flap 150 toward the third target pitch orientation.

In one example, the local controller 112 can: trigger the actuator 140 to drive the tappet 130 toward the flap 150 to locate the flap 150 at a target pitch orientation; read a set of electrical values from an encoder coupled to the actuator 140; derive an initial pitch orientation (e.g., 85°) of the flap 150 based on the set of electrical values; and trigger the actuator 140 to drive the tappet 130 away from the flap 150 to induce oscillatory motion about the pivot axis 124. The local controller 112 can then: access an intermediate pitch orientation (e.g., 45°) for the flap 150 (i.e., specified in the actuation instruction); and, based on the initial pitch orientation (e.g., 85°), predict a particular time (i.e., during oscillatory motion of the flap 150) when the flap 150 intersects the intermediate pitch orientation. In this example, prior to the predicted time, the local controller 112 can trigger the actuator 140 to locate the tappet 130 at a longitudinal position corresponding to the predicted pitch orientation of the flap 150. At the predicted time, the local controller 112 can trigger the actuator 140 to advance the tappet 130 in a direction aligned with angular motion of the flap 150 to contact the flap 150 while the flap 150 moves toward the tappet 130, such that contact reduces relative velocity between the tappet 130 and the flap 150 and limits rebound of the flap 150 following contact.

Therefore, the display unit 110 predicts oscillatory motion of the flap 150 and selectively times re-engagement of the tappet 130 to align actuator-driven displacement with natural motion of the flap 150, thereby reducing rebound and limiting continuous actuator 140 control.

### 14. Controlled Forward+Controlled Return

In one implementation, the local controller 112 can trigger the actuator 140 to: advance the tappet 130 toward the flap 150 such that the tappet 130 maintains contact with the flap 150 while driving angular displacement of the flap 150 about the pivot axis 124; and retract the tappet 130 from the flap 150 such that the tappet 130 maintains contact with the flap 150 while driving angular displacement of the flap 150 about the pivot axis 124 toward the neutral pitch orientation 114. In particular, the local controller 112 can trigger the actuator 140 to drive the tappet 130 toward the flap 150 at a first velocity (e.g., 20 millimeters per second) to: contact the tappet 130 against the flap 150; and rotate the flap 150 about the pivot axis 124 from a neutral pitch orientation 114 (e.g., 0°) to a target pitch orientation (e.g., 90°) while maintaining contact between the tappet 130 and the flap 150. Then, in response to the flap 150 occupying the target pitch orientation, the local controller 112 can trigger the actuator 140 to retract the tappet 130 at a second velocity (e.g., 20 millimeters per second) such that the tappet 130 remains in contact with the flap 150 and rotates the flap 150 about the pivot axis 124 from the target pitch orientation (e.g., 90°) toward the neutral pitch orientation 114 (e.g., 0°). Therefore, the local controller 112 can trigger the actuator 140 to drive the tappet 130 in both forward and reverse directions while maintaining continuous contact between the tappet 130 and the flap 150 to control angular displacement of the flap 150 to and from the target pitch orientation.

### 15. Uncontrolled Forward+Uncontrolled Return

In one implementation, the local controller 112 can trigger the actuator 140 to deliver a mechanical impulse to the flap 150 to induce free rotational motion of the flap 150 about the pivot axis 124 such that the flap 150 transitions from a neutral pitch orientation 114 toward a target pitch orientation and subsequently returns toward the neutral pitch orientation 114 without continuous contact between the tappet 130 and the flap 150. In particular, the local controller 112 can trigger the actuator 140 to position the tappet 130 proximal a contact region of the flap 150 and rapidly advance the tappet 130 toward the flap 150 to impart the mechanical impulse. More specifically, the local controller 112 can trigger the actuator 140 to rapidly advance the tappet 130 such that a magnitude of the impulse corresponds to an initial angular displacement of the flap 150 from the neutral pitch orientation 114 (e.g., 40° or 100°).

In one example, the local controller 112 can trigger the actuator 140 to apply a low-magnitude mechanical impulse that: induces free rotational motion of the flap 150 from the neutral pitch orientation 114 to a target pitch orientation (e.g., 40°); and generates subtle visual effects such as minor surface flickers, soft glints, and localized texture shifts across the multi-panel display 108 resulting from small angular deflections and limited motion blur. In another example, the local controller 112 can trigger the actuator 140 to apply a high-magnitude mechanical impulse that: induces free rotational motion of the flap 150 from the neutral pitch orientation 114 to a target pitch orientation (e.g., 100°); and generates pronounced visual effects such as broad-area reflectance changes, oscillatory specular streaks, and rapid intensity modulation resulting from large angular excursions and relatively higher swing amplitudes.

Therefore, rather than constraining the flap 150 to a fixed pitch orientation through continuous contact during angular displacement, the tappet 130 can apply a mechanical impulse to the flap 150 that induces free rotational motion of the flap 150 about a continuous range of pitch orientations.

### 16. Variation: Staged Velocity Advancement of Tappet

In one variation, as shown in FIG. 3, the local controller 112 can trigger the actuator 140 to advance the tappet 130 toward the flap 150 at a first velocity and subsequently reduce velocity of the tappet 130 prior to contact with the flap 150. More specifically, the local controller 112 can command a rapid initial advancement of the tappet 130 to reduce transition time between a separated state and a pre-contact state and can then command a reduced approach velocity as the tappet 130 nears the flap 150 to minimize mechanical wear and impact-induced vibration during contact. In particular, in this variation, in response to receiving a start command (e.g., issued by the primary controller 104), the local controller 112 can trigger the actuator 140 to advance the tappet 130 toward the flap 150 at a first velocity. The local controller 112 can then trigger the actuator 140 to decelerate the tappet 130 toward a second velocity, less than the first velocity, prior to contact between the tappet 130 and the flap 150, the second velocity selected: to locate the flap 150 in the target pitch orientation at the time; and to reduce mechanical vibration of the flap 150 at impact with the tappet 130.

Additionally, following angular displacement of the flap 150 toward the target pitch orientation, the local controller 112 can trigger the actuator 140 to retract the tappet 130 from the flap 150 at a third velocity exceeding the first velocity: to locate the tappet 130 behind the neutral pitch orientation 114 following separation from the flap 150 (i.e., clear the tappet 130 from a path of oscillatory motion of the flap 150); and to permit the flap 150 to oscillate through pitch orientations located rearward of the neutral pitch orientation 114.

Therefore, by advancing the tappet 130 at a first velocity to reduce transition time and decelerating the tappet 130 to a second velocity prior to contact with the flap 150, the display unit 110 can reduce impact-induced vibration while maintaining time-accurate positioning of the flap 150, thereby preserving smooth oscillatory motion following separation.

### 17. Variation: Sequential Instructions for Array of Display Units

In one variation, the display system 100 can include an array of display units 110, each display unit 110 configured to independently drive a flap 150 to a target pitch orientation at a target time such that the array of display units 110 collectively forms an animated image, pattern, or texture at the multi-panel display 108. In this variation, a primary controller 104 (and/or a set of column controllers 106) can cooperate with local controllers 112 of each display unit 110 in the array of display units 110 to distribute, sequence, and synchronize actuation instructions across the array.

In one example, the array of display units 110 includes: a first display unit; and a second display unit configured to install adjacent the first display unit (e.g., in a column of display units). In this example, the display system 100 further includes a column controller 106: serially coupled to the first local controller and the second local controller; and configured to receive a set of actuation instructions from a primary controller 104 and pass the set of actuation instructions to the first display unit (e.g., a “primary” display unit). The first local controller of the first display unit can then: read motion parameters (e.g., a first target pitch orientation) from a first instruction, in the set of actuation instructions, assigned to the first display unit; and pass the set of actuation instructions to the second display unit. The second local controller of the second display unit can then: receive the set of actuation instructions from the first display unit; and read motion parameters from a second instruction, in the set of actuation instructions, assigned to the second display unit.

For example, the first local controller can: read a first instruction assigned to the first display unit, the first instruction specifying a first function defining a first relationship between angular displacement of a first flap 150 of the first display unit and time; derive a first target pitch orientation for angularly displacing the first flap 150 at a first time based on the function; and trigger a first actuator 140 of the first display unit to advance a first tappet 130 of the first display unit toward the first flap 150 to angularly displace the first flap 150 toward the first target pitch orientation at the first time.

Additionally, the second local controller can: read a second instruction assigned to the second display unit, the second instruction specifying a second function defining a second relationship between angular displacement of a second flap 150 of the second display unit and time; derive a second target pitch orientation for angularly displacing the second flap 150 at the first time based on the function; and trigger a second actuator 140 of the second display unit to advance a second tappet 130 of the second display unit toward the second flap 150 to angularly displace the second flap 150 toward the second target pitch orientation at the first time.

In another example, the column controller 106 can disseminate the set of actuation instructions to each display unit 110 in parallel rather than serially passing the set of actuation instructions between adjacent display units 110. Therefore, the display system 100 distributes actuation instructions across the array and executes time-aligned flap displacement at multiple display units 110 to generate coordinated visual motion while permitting each display unit 110 to independently calculate and execute its assigned motion parameters.

### 18. Installation

In one implementation, the display unit 110 can be installed on a surface 190, such as a planar vertical wall. In particular, the chassis 120 can include a mounting bracket configured to couple the chassis 120 to a rear side (e.g., a non-visible side) of the surface. In this implementation, the tappet 130 can extend longitudinally from the chassis 120, through a mounting aperture 192 defined in the surface, to locate the flap 150 proximal a front side (e.g., a visible side) of the surface when the chassis 120 is mounted to the surface. For example, during installation of the display unit 110, an operator may: insert the chassis 120 through the mounting aperture 192 (or insert the tappet 130 through the mounting aperture 192); install the chassis 120 to the rear side of the surface at the mounting bracket; and install the façade panel 154 to the backing plate 152 of the flap 150.

Accordingly, the display unit 110 locates the actuator 140 and local controller rearward of the surface and locates the flap 150 forward of the surface 190 without a fixed mechanical linkage requiring disassembly for separation. More specifically, the chassis 120 retains the actuator 140 and local controller at the rear side of the surface 190, while the flap 150 remains independently detachable at the front side of the surface 190. Thus, the display unit 110 isolates the drive system from the visual element to permit replacement of the flap 150 without disturbing electrical or drive components mounted rearward of the surface 190.

### 19. Setup and Calibration

In one variation, the display unit 110 can initiate a calibration routine to generate a calibration map between longitudinal displacement of the tappet 130 and angular displacement of the flap 150 about the pivot axis 124. For example, the calibration map can define a one-to-one relationship between encoder values corresponding to tappet position and sensor values corresponding to pitch orientation of the flap 150 about the pivot axis 124. In this variation, the display unit 110 can include: an encoder coupled to the actuator 140 and configured to output electrical values representing longitudinal displacement of the tappet 130 relative to the chassis 120; and an angular orientation sensor (e.g., an encoder, a Hall effect sensor) mechanically coupled to the pivot axis 124 of the flap 150 and configured to output electrical values representing angular displacement of the flap 150 about the pivot axis 124 relative to the neutral pitch orientation 114.

In particular, during the calibration routine, the local controller 112 can: trigger the actuator 140 to drive the tappet 130 across a range of longitudinal positions (e.g., from a fully retracted position to a forward-most position); read encoder values representing the longitudinal positions of the tappet 130 while the actuator 140 drives the tappet 130 across the range of longitudinal positions; read corresponding pitch orientation values of the flap 150 from the angular orientation sensor; and store each encoder-sensor value pair as a datapoint in a tappet-to-angle calibration map. The local controller 112 can then repeat this process at multiple longitudinal displacements to populate the calibration map with a set of discrete encoder-to-angle relationships. The local controller 112 can further interpolate between stored values during runtime to estimate intermediate angular orientations from real-time encoder readings.

Therefore, the display unit 110 can: store the tappet-to-angle calibration map in local memory as a reference data structure; and interpret real-time encoder values during actuation instructions to calculate accurate angular orientations of the flap 150 during pendulum motion.

### 20. Variation: Backlit Flap

In one variation, as shown in FIG. 5B, the display unit 110 can further include a light element 180 (e.g., a light-emitting diode) configured to back-light the flap 150. For example, the display unit 110 can include a light element 180 arranged behind the flap 150, such as mounted to the chassis 120 or installed on a printed circuit board (e.g., with the local controller 112 and an actuator driver) arranged between the chassis 120 and the flap 150.

In one example, the chassis 120 is configured to install on a rear side of a surface 190 (e.g., via a mounting bracket), such that the tappet 130 extends longitudinally from the chassis 120, through a mounting aperture 192 defined in the surface 190, to locate the flap 150 proximal a front side of the surface 190. In this example, the display unit 110 further includes a light element 180: arranged on the chassis 120; electrically coupled to the local controller 112; and configured to project light through the mounting aperture 192 to back-light the flap 150.

In particular, the façade panel 154 of the flap 150 can exhibit visual characteristics selected to interact with light emitted by the light element 180. More specifically, the façade panel 154 can define opposing surfaces exhibiting different optical transparency, reflectivity, translucency, color, or surface finishes such that rotation of the flap 150 alters transmission, diffusion, or reflection of back-projected light at the multi-panel display 108. Thus, the display unit 110 locates the chassis 120, light element 180, and actuator 140 hardware rearward of the surface 190 while presenting an illuminated façade at the front side of the surface 190, and integrates backlighting within the chassis 120 to reduce external wiring and simplify assembly of the display system 100.

In another example, the display unit 110 further includes a light element 180 configured to project light to back-light the surface. In particular, in this example, when the flap 150 rotates from the neutral pitch orientation, the light element 180 can back-light the surface, such that an illuminated façade is presented at the display 108.

### 21. Variation: Horizontal Flap

In one variation, the display unit 110 can be installed on a horizontal surface 190 (e.g., a ceiling, floor, or horizontal panel) such that the flap 150 pivots about a horizontal pivot axis 124. In this variation, the tappet 130: extends vertically from the chassis 120 toward the rear surface 158 of the flap 150; and is configured to convert rotational output of the actuator 140 into vertical motion that drives angular displacement of the flap 150.

In one example, the tappet 130 can be mechanically coupled to the flap 150 such that the actuator 140 drives angular displacement of the flap 150 in both a forward direction and a return direction (e.g., without relying on gravitational bias). Alternatively, the display unit 110 can further include a spring element configured to restore the flap 150 toward the neutral pitch orientation 114 following retraction of the tappet 130. In one example, the spring element can include a torsion spring arranged at the pivot axis 124 and configured to apply a restoring torque to the flap 150 as the flap 150 displaces from the neutral pitch orientation 114.

In this variation, the tappet 130 can further include a damping element (e.g., an elastomeric pad or compliant insert): arranged at the distal end of the tappet 130; and configured to contact the backing plate 152 of the flap 150 during advancement of the tappet 130 toward the flap 150 and to compress upon contact with the flap 150, such as to attenuate impact forces transmitted from the tappet 130 to the flap 150 and reduce transmission of high-frequency mechanical vibrations during impact.

### 22. Disclaimer

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor, but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A system comprising:
a first display unit comprising:
a first chassis;
a first flap:
pivotably coupled to a first distal end of the first chassis;
gravitationally biased toward a first neutral pitch orientation;
comprising:
a first display surface facing outwardly from the first chassis; and
a first rear surface opposite the first display surface; and
configured to pivot about a first pivot axis over a range of angular pitch orientations;
a first tappet supported by the first chassis;
a first actuator; and
a first local controller configured to trigger the first actuator to:
advance the first tappet toward the first rear surface of the first flap to angularly displace the first flap from the first neutral pitch orientation toward a first target pitch orientation; and
retract the first tappet from the first flap to release the first flap to oscillate through the range of angular pitch orientations.

2. The system of claim 1, wherein the first actuator is configured to:
advance the first tappet toward the first flap to:
locate the first tappet in contact with the first flap; and
angularly displace the first flap toward the first target pitch orientation located forward of the first neutral pitch orientation to increase potential energy of the first flap; and
retract the first tappet to separate the first tappet from the first flap and release the first flap to:
oscillate past the first neutral pitch orientation; and
passively return to the first neutral pitch orientation.

3. The system of claim 1:
further comprising a panel comprising a set of apertures;
wherein the first chassis is configured to install on the panel with:
the first distal end of the first chassis and a distal end of the first tappet extending through a first aperture in the set of apertures; and
the first actuator located behind the panel;
further comprising a first light element configured to back-light the panel; and
wherein the first flap is pivotably coupled to the first distal end of the first chassis in front of the panel and exposes a first portion of the panel proportional to angular displacement of the first flap from the first neutral pitch orientation.

4. The system of claim 3:
wherein the first display surface of the first flap exhibits a first color;
wherein the first portion of the panel exhibits a second color different from the first color;
wherein the first flap and the first portion of the panel cooperate to define a pixel exhibiting a continuous grayscale transition between the first color and the second color; and
wherein the first local controller is configured to:
access a first instruction specifying a first grayscale value;
trigger the first actuator to drive the first tappet to angularly displace the first flap to the first target pitch orientation to yield the first grayscale value; and
trigger the first actuator to retract the first tappet to release the first flap to oscillate between the first grayscale value and a second grayscale value.

5. The system of claim 1, wherein the first local controller is configured to:
following angular displacement of the first flap toward the first target pitch orientation:
trigger the first actuator to retract the first tappet to separate the first tappet from the first flap at a first time;
calculate a second pitch orientation of the first flap at a second time, following the first time; based on:
the first target pitch orientation;
a difference between the first time and the second time; and
a first natural frequency of the first flap;
based on the second pitch orientation, derive a second target longitudinal position for the first tappet to contact the first flap at the second time while the first flap oscillates through the range of angular pitch orientations; and
trigger the first actuator to drive the first tappet toward the second target longitudinal position at the second time to engage the first flap prior to the first flap returning to rest at the first neutral pitch orientation.

6. The system of claim 1, wherein the first local controller is configured to:
access a first instruction assigned to the first display unit by a primary controller;
derive the first target pitch orientation for the first flap at a first time based on the first instruction;
calculate a first target longitudinal displacement for the first tappet that corresponds to angular displacement of the first flap from the first neutral pitch orientation toward the first target pitch orientation; and
trigger the first actuator to rotate to an angular position that locates the first tappet at the first target longitudinal displacement to angularly displace the first flap to the first target pitch orientation at the first time.

7. The system of claim 1, further comprising:
a second display unit:
configured to install adjacent the first display unit; and
comprising:
a second chassis;
a second flap:
pivotably coupled to a second distal end of the second chassis;
gravitationally biased toward a second neutral pitch orientation;
comprising:
a second display surface cooperating with the first display surface of the first display unit to define a multi-panel; and
a second rear surface opposite the second display surface; and
configured to pivot about a second pivot axis over the range of angular pitch orientations;
a second tappet supported by the second chassis;
a second actuator; and
a second local controller configured to trigger the second actuator to:
advance the second tappet toward the second rear surface of the second flap to angularly displace the second flap from the second neutral pitch orientation toward a second target pitch orientation; and
retract the second tappet from the second flap to release the second flap to oscillate through the range of angular pitch orientations; and
a primary controller configured to disseminate actuation instructions to the first display unit and the second display unit.

8. The system of claim 7:
wherein the second display unit is arranged adjacent the first display unit in a column of display units;
further comprising a column controller:
serially coupled to the first local controller and the second local controller; and
configured to:
receive a set of actuation instructions from the primary controller; and
pass the set of actuation instructions to the first display unit;
wherein the first local controller is configured to:
read a first instruction, in the set of actuation instructions, assigned to the first display unit;
derive the first target pitch orientation for the first flap based on the first instruction; and
pass the set of actuation instructions to the second display unit; and
wherein the second local controller is configured to:
read a second instruction, in the set of actuation instructions, assigned to the second display unit; and
derive the second target pitch orientation for the second flap based on the second instruction.

9. The system of claim 1:
wherein the first tappet further comprises a first slot extending laterally along the first tappet; and
wherein the first actuator comprises a first pin:
eccentrically coupled to a first output shaft of the first actuator; and
configured to run within the first slot to longitudinally translate the first tappet within the first chassis responsive to rotation of the first output shaft.

10. The system of claim 1:
wherein the first chassis comprises a first mounting slot configured to:
couple the first actuator to the first chassis; and
locate the first actuator over a range of longitudinal positions relative to the first flap; and
wherein the first actuator is configured to mount to the first chassis, via the first mounting slot, at a longitudinal position that locates the first actuator at a target distance from the first pivot axis to achieve the range of angular pitch orientations.

11. The system of claim 1, wherein the first tappet:
comprises a first magnetic element arranged proximal a distal end of the first tappet; and
is configured to:
magnetically couple to the first flap, via the first magnetic element, following contact with the first flap;
maintain magnetic coupling with the first flap, via the first magnetic element, when retracted from the first flap at a first retraction velocity less than a threshold velocity; and
magnetically decouple from the first flap when retracted from the first flap at a second retraction velocity greater than the threshold velocity.

12. The system of claim 1, wherein the first actuator is configured to:
drive the first tappet in a first direction toward the first rear surface of the first flap at a first velocity;
decelerate the first tappet in the first direction toward a second velocity, less than the first velocity, prior to contact with the first flap; and
retract the first tappet from the first flap at a third velocity, exceeding the first velocity, to:
locate the first tappet behind the first neutral pitch orientation following separation from the first flap; and
release the first flap to oscillate through angular pitch orientations rearward of the first neutral pitch orientation.

13. The system of claim 1, wherein the first flap comprises a first counterweight configured to:
locate over range of positions on the first flap to locate a first center of mass of the first flap at a target offset from the first pivot axis, the target offset corresponding to a target natural frequency for the first flap; and
gravitationally bias the first flap toward the first neutral pitch orientation while the first flap oscillates about the first pivot axis following retraction of the first tappet.

14. A method comprising:
at a first display unit:
receiving a first instruction assigned to the first display unit by a primary controller;
based on the first instruction, deriving a first target pitch orientation for angularly displacing a first flap, pivotably coupled to a first chassis of the first display unit, at a first time; and
via a first actuator of the first display unit:
advancing a first tappet, interposed between the first chassis and the first flap, toward the first flap to:
locate the first tappet in contact with the first flap; and
angularly displace the first flap toward the first target pitch orientation at the first time; and
retracting the first tappet from the first flap to:
separate the first tappet from the first flap; and
release the first flap to oscillate.

15. The method of claim 14:
wherein deriving the first target pitch orientation for angularly displacing the first flap comprises:
reading a function, defining a relationship between angular displacement of the first flap and time, from the first instruction; and
deriving the first target pitch orientation for the first flap at the first time based on the function; and
wherein advancing the first tappet toward the first flap via the first actuator comprises:
calculating a first target longitudinal displacement for driving the first tappet to locate the first flap in the first target pitch orientation; and
advancing the first tappet toward the first flap according to the first target longitudinal displacement.

16. The method of claim 14:
wherein receiving the first instruction at the first display unit comprises:
receiving a set of actuation instructions comprising the first instruction; and
reading the first instruction from the set of actuation instructions; and
further comprising, at a second display unit:
receiving the set of actuation instructions from the first display unit;
reading a second instruction, from the set of actuation instructions, assigned to the second display unit;
based on the second instruction, deriving a second target pitch orientation for angularly displacing a second flap, pivotably coupled to a second chassis of the second display unit, at the first time; and
advancing a second tappet, interposed between the second chassis and the second flap, toward the second flap to angularly displace the second flap toward the second target pitch orientation at the first time.

17. The method of claim 14:
wherein advancing the first tappet toward the first flap via the first actuator comprises:
advancing the first tappet toward the first flap at a first velocity; and
decelerating the first tappet toward a second velocity, less than the first velocity, prior to contact between the first tappet and the first flap to reduce mechanical vibration of the first flap at impact with the first tappet; and
wherein retracting the first tappet from the first flap via the first actuator comprises:
retracting the first tappet from the first flap at a third velocity, exceeding the first velocity, to release the first flap to oscillate past a first neutral pitch orientation of the first flap.

18. The method of claim 14, further comprising, at the first display unit:
calculating a second pitch orientation of the first flap at a second time, following the first time, based on:
the first target pitch orientation;
a difference between the first time and the second time; and
a first natural frequency of the first flap; and
via the first actuator of the first display unit:
advancing the first tappet toward the first flap to angularly displace the first flap from the second pitch orientation toward a third target pitch orientation at the second time.

19. The method of claim 14, further comprising, at the first display unit
receiving a second instruction assigned to the first display unit;
based on the second instruction, deriving a second target pitch orientation for angularly displacing the first flap at a second time; and
via the first actuator of the first display unit:
advancing the first tappet, in a first direction, toward the first flap to angularly displace the first flap toward the second target pitch orientation at the second time; and
retracting the first tappet, in a second direction, while maintaining contact between the first tappet and the first flap.

20. A display unit comprising:
a flap:
pivotably coupled to a chassis;
comprising a display surface facing outwardly from the chassis; and
configured to pivot about a pivot axis over a range of angular pitch orientations;
a tappet supported by the chassis; and
an actuator:
arranged in the chassis; and
configured to:
advance the tappet toward the flap to:
drive the tappet into contact with the flap; and
drive the flap toward a target pitch orientation; and
retract the tappet to:
separate the tappet from the flap; and
release the flap to oscillate over the range of angular pitch orientations.
